(19) United States
(12) Patent Application Publication
(10) Pub. No.: US 2007/0298754 A1
(43) Pub. Date: Dec. 27, 2007

(54) Conversion of Vehicle Sound System From Installed To Portable Sound Source

(75) Inventors: Roger Alves, Camarillo, CA (US); Nathan Perkins, Camarillo, CA (US); Jeremy C. Prater, Oxnard, CA (US)

Correspondence Address: MCDERMOTT WILL & EMERY LLP, 2049 CENTURY PARK EAST, 38th Floor, LOS ANGELES, CA, 90067-3208, US

(73) Assignee: Scosche Industries, Inc.

(21) Appl. No.: 11/426,267

(22) Filed: Jun. 23, 2006

(51) Int. Cl. H05K 11/02

(52) U.S. Cl. 455/350; 455/345

(57) ABSTRACT

Conversion of a vehicle sound system from an installed to a portable sound source. A wireless personal area network receiver may be substituted for the radio and/or media player that is normally found within the vehicle.

### BACKGROUND

1. Field

Vehicle sound systems and portable media players.

2. Description of Related Art

Vehicle sound systems have become commonplace. Although not yet as popular, portable media players, such as MP3 players or iPods, are also in widespread use.

Portable media players usually do not include a high-powered sound reproduction system. On the other hand, vehicle sound systems usually are not able to be used easily outside of the vehicle and usually do not have much flexibility in programming the material that is played back. Having to purchase both types of systems and to stock both of them with media content may also be costly and time-consuming.

### SUMMARY

A process may modify a vehicle sound system that includes a radio receiver and/or a media player located in a cavity behind a panel within the vehicle and that is connected to power and audio cables. The process may include removing the radio receiver and/or media player from the cavity, disconnecting the power and audio cables from the radio receiver and/or media player, connecting the power and audio cables to a wireless personal area network receiver, and positioning the wireless personal area network receiver in the cavity behind the panel.

A kit may modify a vehicle sound system that includes a radio receiver and/or a media player that is positioned in a cavity behind a panel within the vehicle and that is connected to power and audio cables. The kit may include a wireless personal area network receiver configured to be connected to the power and audio cables in lieu of the power and audio cables being connected to the radio receiver and/or the media player. The kit may also include a mounting apparatus configured to securely hold the wireless personal area network receiver, to replace the radio receiver and/or the media player with the wireless personal area network receiver, and to securely fit within the cavity behind the panel. The kit may also include media containing instructions on how to replace the radio receiver and/or the media player with the wireless personal area network receiver.

A vehicle sound system may include a source of power within the vehicle, one or more audio amplifiers within the vehicle, power cables connected to the source of power, audio cables connected to the one or more audio amplifiers, and a wireless personal area network receiver connected to the power cables and to the audio cables. The vehicle sound system may not include either a radio receiver or a media player connected by wire to any of the one or more audio amplifiers.

These, as well as other components, steps, features, objects, benefits, and advantages, will now become clear from a review of the following detailed description of illustrative embodiments, the accompanying drawings, and the claims.

### BRIEF DESCRIPTION OF DRAWINGS

FIG. 1 illustrates certain components of a kit for modifying a vehicle sound system.

FIG. 2 illustrates the components shown in FIG. 1 after they are assembled and positioned for further assembly with another component of the kit.

FIG. 3 illustrates an assembled kit for modifying a vehicle sound system.

FIG. 4 illustrates written instructions on how to modify a vehicle sound system.

FIGS. 5a-5d illustrate a process for modifying a vehicle sound system.

FIG. 6 illustrates a front plate being removed to gain access to a user-operable control in a vehicle sound system.

### DETAILED DESCRIPTION OF ILLUSTRATIVE EMBODIMENTS

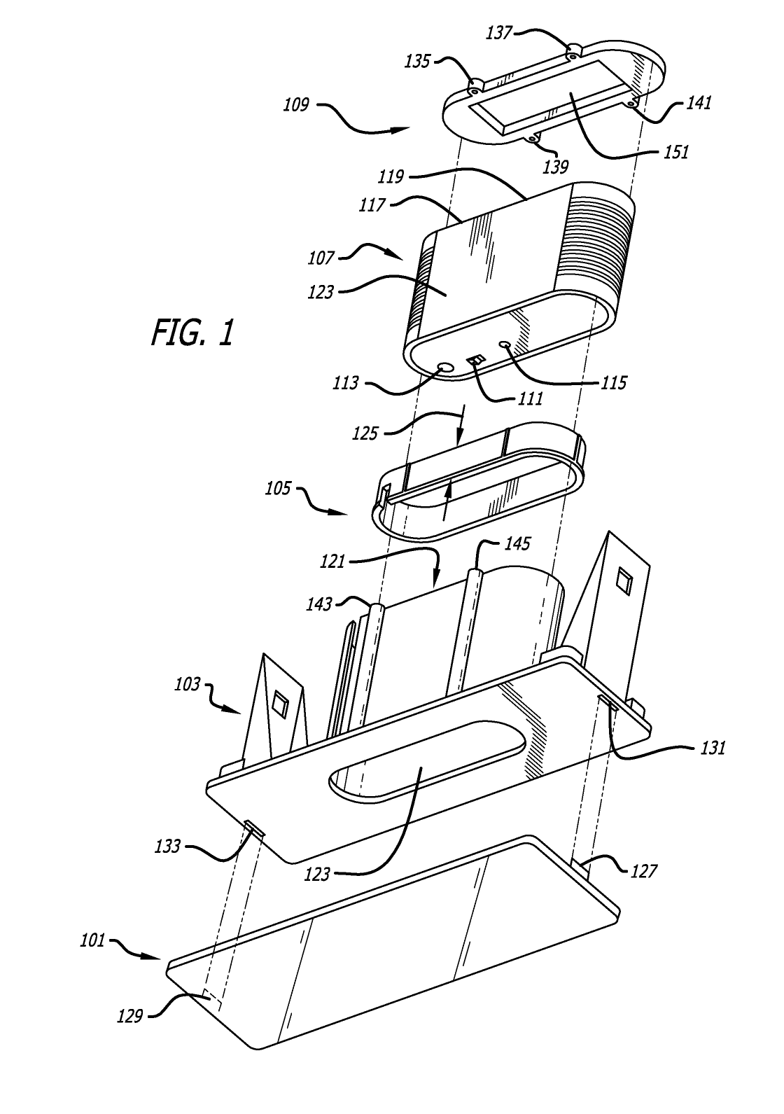

FIG. 1 illustrates certain components of a kit for modifying a vehicle sound system.

As shown in FIG. 1, the kit may include a cover plate 101, a mounting bracket 103, a spacer 105, a wireless personal area network receiver 107, and a back plate 109.

The wireless personal area network receiver 107 may be any type of wireless personal area network receiver. As is well known, a wireless personal area network receiver is configured to receive wireless signals from a close distance, typically from only a few meters. A well known example of a wireless personal area network receiver is a Bluetooth receiver. Other examples include receivers that conform to the IEEE 802.11 standard and ultra-wide band receivers.

The wireless personal area network receiver 107 may be configured to communicate with a wireless personal area network transmitter that, in turn, may be connected to a media player, such as an MP3 player or an iPod. The wireless personal area network transmitter may in addition or instead be connected to a cell phone, a radio receiver, or to any other type of sound-generating device.

A wireless transmitter may be included along with the wireless personal area network receiver 107, either within the same housing or a different housing. Operating in conjunction with the wireless personal area network receiver 107, the wireless personal area network transmitter may transmit signals back to the device from which a wireless signal is received. The combination of a wireless personal area network receiver and a wireless personal area network transmitter is often referred to as a wireless personal area network transceiver. An example is using Bluetooth to communicate wirelessly with a cell phone. One purpose of such a wireless, bi-directional communication link may be broadcast sound that is received by the cell phone over a loud speaker in a vehicle and to deliver sound that is picked up by a hands-free microphone positioned within the vehicle (e.g., on a visor) back over the cellular network.

The wireless personal area network receiver 107 may include one or more user-operable controls, such as a power switch 111. It may include one or more user-accessible connections, such as a microphone jack 113. It may include one or more user-viewable indicators, such as an LED power indicator 115.

The wireless personal area network receiver 107 may include one or more output connectors to which cabling may be connected, such as audio cables connected to one or more amplifiers. These may be positioned at the rear of the receiver 107.

The wireless personal area network receiver 107 may include one or more power input connectors to which one or more power cables may be connected. These may be positioned at the rear of the receiver.

The mounting bracket 103 may be configured to include a cavity 121 into which the wireless personal area network receiver 107 may be inserted. The cavity 121 may have a shape that is substantially the same as an outer surface 123 of the wireless personal area network receiver, so as to ensure that the wireless personal area network receiver 107 fits snugly within the cavity 121.

The mounting bracket 103 may have a front-facing opening 123 through which a user may access user-operable controls, such as the user-operable control 111; user-accessible connections, such as the microphone jack 113; and/or to allow a user to view user-viewable indicators, such as the LED 115.

The spacer 105 may be configured to fit within the opening 121. The spacer 105 may be configured to insure that the wireless personal area network receiver 107 is spaced back from the opening 123 in the mounting bracket 103.

The cover plate 101 may include protruding tabs 127 and 129 configured to snap into corresponding openings 131 and 133 in the mounting bracket 103. This may allow the cover plate 101 to be easily attached to and detached from the mounting bracket 103. The cover plate 101 may be semi-transparent so as to allow a user to see user-visible indicators on the wireless personal area network receiver 107, such as the LED 115.

Several cover plates may be supplied with the kit, each in a different color. The user may select which looks best in view of the surrounding colors and use this for the cover plate 101.

A mechanism may be included to allow the back plate 109 to be attached to the mounting bracket 103. This may include holes 135, 137, 139, and 141 in the back plate 109, corresponding holes in the mounting bracket 103, including corresponding holes 143 and 145, and fastening means, such as screws (not shown), that may be inserted through the holes in the back plate 109 and screwed into the corresponding holes in the mounting bracket 103. Other attachment mechanisms, such as tabs and corresponding openings, may be used in addition or instead.

The back plate 109 may have an opening 151 oriented to provide access to connectors on the back of the wireless personal area network receiver 107, while at the same time ensuring that the wireless personal area network receiver 107 does not fall out of the cavity 121 in the mounting bracket 103.

The kit may be assembled by attaching the cover plate 101 to the mounting bracket 103, inserting the spacer 105 into the cavity 121 of the mounting bracket 103, inserting the wireless personal area network receiver 107 into the cavity 121 of the mounting bracket 103, and attaching the back plate 109 to the rear of the mounting bracket 103 by inserting screws through the holes 135,137,139, and 141 and screwing them into corresponding holes in the mounting bracket 103, including holes 143 and 145. A different assembly sequence may be used instead. For example, the cover plate 101 need not be attached first.

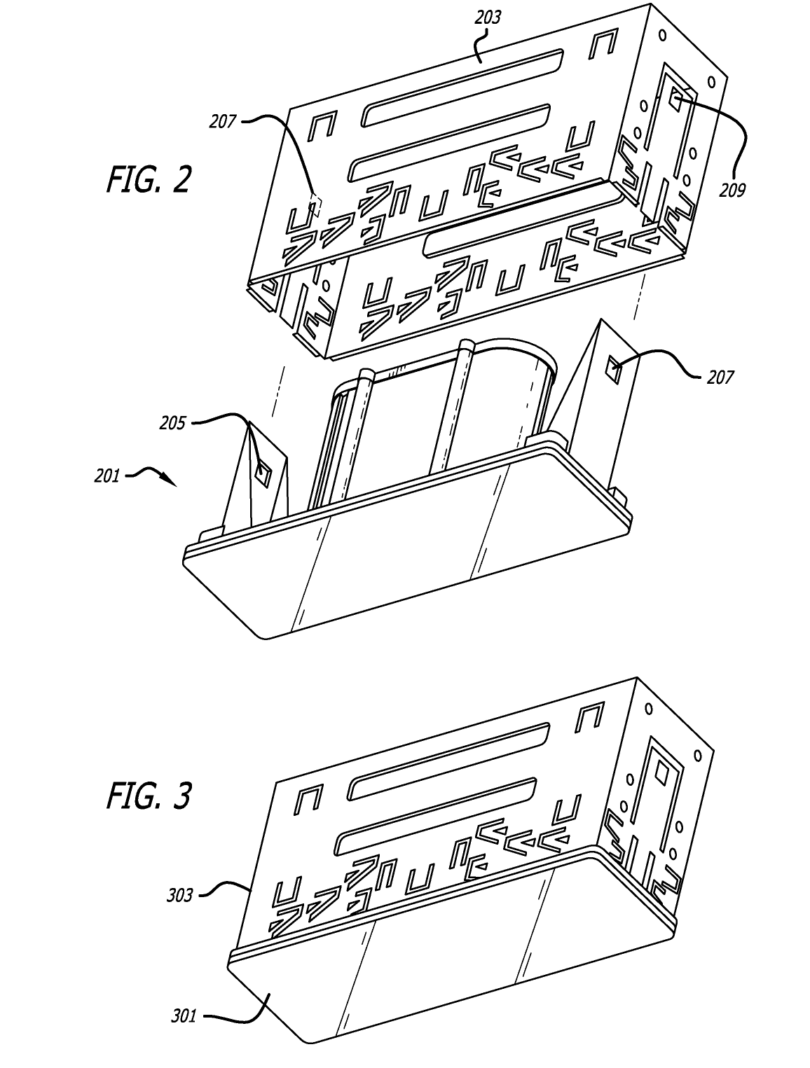

FIG. 2 illustrates the components of the kit for modifying a vehicle sound system that are shown in FIG. 1 after they are assembled and positioned for further assembly with another component of the kit. As shown in FIG. 2, an assembly 201 may be positioned for insertion into a DIN sleeve 203. The assembly 201 may include the cover plate 101, the mounting bracket 103, the spacer 105, the wireless personal area network receiver 107, and the back plate 109 configured and assembled as discussed above in connection with FIG. 1. It may also or instead include a different set and/or configuration of components, such as a wireless personal area network receiver of a different type or in a different configuration than the wireless personal area network receiver 107 shown in FIG. 1.

The DIN sleeve 203 may be a standard, off-the-shelf DIN sleeve. The sleeve may be configured to snap into a cavity behind an opening in a vehicle panel. The size and configuration of the DIN sleeve 203 may vary.

The assembly 201 may be inserted and snapped into a locked position in the DIN sleeve 203. The assembly 201 may be configured so as to fit snugly within the DIN sleeve 203. The assembly 201 may include openings 205 and 207 that are sized and oriented to snap onto corresponding inwardly-protruding tabs on the DIN sleeve 203, such as a tab 209. The DIN sleeve may include other openings, tabs, and/or other mechanisms to facilitate engagement of the DIN sleeve 203 in a cavity behind an opening in a vehicle panel.

FIG. 3 illustrates an assembly kit for modifying a vehicle sound system. It may include an assembly 301 of the type described above in connection with FIG. 2 or of any other type. It may include a DIN sleeve 303 of the type discussed above in connection with FIG. 2 or of any other type.

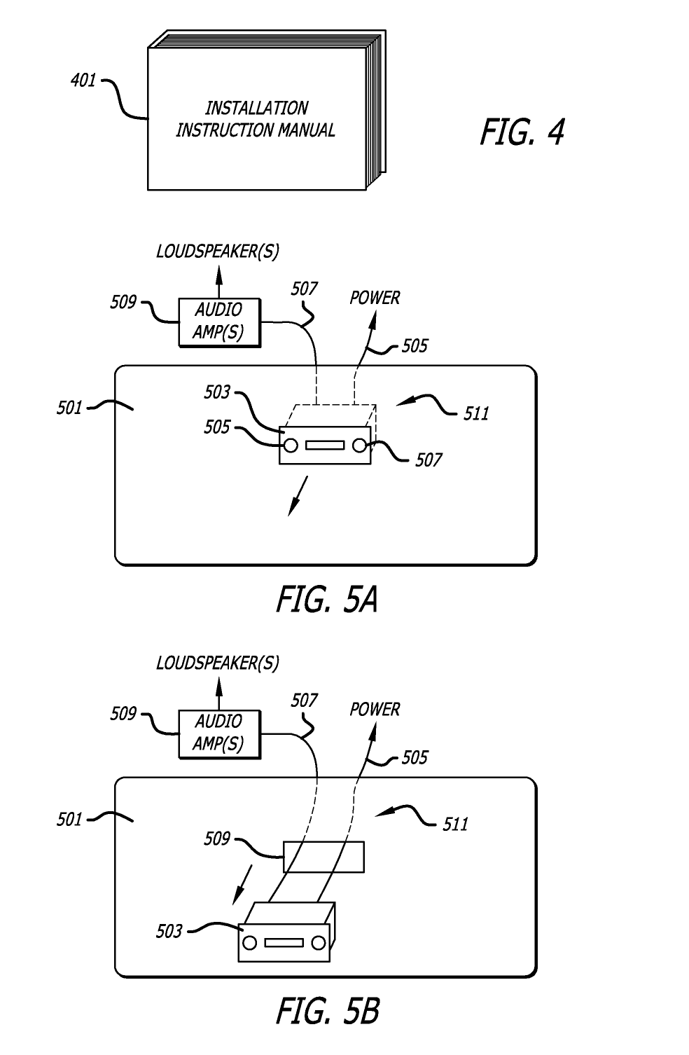

FIG. 4 illustrates written instructions of how to modify a vehicle sound system. As shown in FIG. 4, the written instructions may include an installation instruction manual 401. The installation instruction manual 401 may explain that the sound system may be modified in accordance with the structures and processes described herein. The installation instruction manual 401 may include appropriate textual material, drawings and/or photographs. The manual 401 may be contained on any type of media, such as paper and/or computer-readable media, such as one or more CDs, DVDs, floppies, and/or memory cards. The installation instruction manual 401 may include multimedia content.

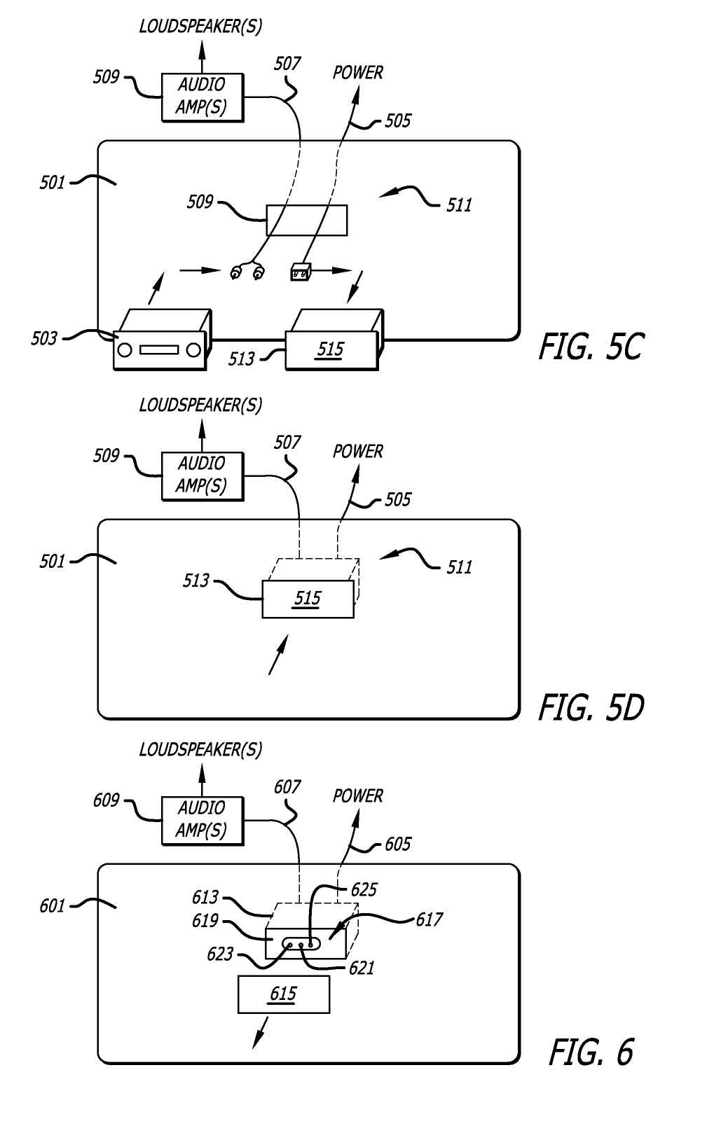

FIGS. 5a-5d illustrate a process for modifying a vehicle sound system.

As shown in FIG. 5a, a vehicle may have a panel 501. The panel may face or neighbor a driver or passenger of the vehicle and be accessible to a person sitting in a front or rear or other seat.

The panel 501 may have a radio receiver and/or media player 503 mounted on it. The radio receiver and/or media player 503 may be connected to a power cable 505, to an antenna cable (not shown), and to one or more audio cables 507. The audio cables 507 may be connected to one or more audio amps 509 that may be connected to one or more loudspeakers (not shown).

The radio receiver and/or media player 503 may include one or more user controls 505 and 507, and may be configured to tune in one or more radio stations, such as one or more AM, FM, and/or satellite stations. The radio receiver and/or media player 503 may be configured to deliver sound from the selected station to the one or more audio cables 507. The radio receiver and/or media player 503 may in addition or instead be configured to play media containing sound information, such as a CD, DVD, floppy disk, cassette, and/or memory stick.

The panel 501 may include other user-accessible controls, displays or devices (not shown).

The radio receiver and/or media player 503 may extend rearwardly behind the panel 501 through an opening in the panel 509 (see FIG. 5b) and into a cavity 511. The cavity 511 may be an open area of space that has been allotted to contain the rearward extension of the radio receiver and/or media player 503. It may include a sleeve or other mechanism (not shown) configured to attach to the radio receiver and/or media player 503 so as to secure it within the cavity 511.

The radio receiver and/or media player 503 may be removed from the cavity 511, as shown in FIG. 5b. The steps taken to effectuate this removal may depend upon the vehicle model. In the example shown in FIG. 5b, the radio receiver and/or media player 503 may be pulled in a forward manner from the opening 509. In other models, the radio receiver and/or media player 503 may need to be moved rearwardly in order to effectuate its removal from the cavity 511.

Either before or after the radio receiver and/or media player 503 is removed from the cavity 511, the power cable 505 and the one or more audio cables 507 may be disconnected from the radio receiver and/or media player 503, as shown in FIG. 5c, along with any antenna or other cable(s) that may be connected.

The power cable 505 and the one or more audio cables 507 may then be connected to a wireless personal area network receiver that is part of a wireless personal area network receiver assembly 513. This wireless personal area network receiver assembly 513 may contain one or more of the components that were discussed above in connection with FIGS. 1-3. The wireless personal area network receiver assembly 513 may then be placed within the cavity 511, as shown in FIG. 5d. This may be effectuated by sliding the wireless personal area network receiver assembly 513 through the opening 509 and into a sleeve or other securing apparatus behind the panel 501. The nature and configuration of the securing apparatus may depend upon the vehicle model. In an alternate embodiment, the power cable 505 and the one or more audio cables 507 may be connected to the wireless personal area network receiver assembly 513 after the assembly is placed within the cavity 511 or during the process of doing so.

The modified vehicle sound system shown in FIG. 5d may be used to wirelessly receive audio information from a wide variety of sources to which a wireless transmitter has been attached, including a portable media player, such as an MP3 player and/or an iPod, a cell phone, and/or a laptop computer. With this configuration, there may no longer be a need for the vehicle to have a media player connected by wires to either the source of power or the audio amplifiers to which the wireless personal area network receiver is connected.

The portable device with which the wireless personal area network receiver communicates may instead or in addition include a radio receiver, such as an FM, AM, and/or satellite radio receiver. With this configuration, there may no longer be a need for the vehicle to have a radio receiver connected by wires to either the source of power or the audio amplifiers to which the wireless personal area network receiver is connected.

The wireless personal area network receiver assembly 513 may include a front plate 515 that contains no user-accessible controls, connections, and/or displays. The front plate 515 may be configured to be removable by a user to expose user-accessible controls, connections, and/or displays.

FIG. 6 illustrates a front plate being removed to gain access to a user-operable control in a vehicle sound system. As shown in FIG. 6, a front plate 615 may be removed from a wireless personal area network receiver assembly 613. The receiver assembly 613 may be mounted on a panel 601 of a vehicle and attached by one or more audio cables 607 to one or more audio amps 609 and a power cable 605 to power. Upon removal of the front plate 615, an opening 617 in a front portion 619 of the wireless personal area network receiver assembly 613 may provide access to a user-operable control 621, as well as to a microphone jack 623 and an LED indicator 625.

The components, steps, features, objects, benefits and advantages that have been discussed are merely illustrative. None of them, nor the discussions relating to them, are intended to limit the scope of protection in any way. Numerous other embodiments are also contemplated, including embodiments that have fewer, additional, and/or different components, steps, features, objects, benefits and advantages. The components and steps may also be arranged and ordered differently.

In short, the scope of protection is limited solely by the claims that now follow. That scope is intended to be as broad as is reasonably consistent with the language that is used in the claims and to encompass all structural and functional equivalents. Nothing that has been stated or illustrated is intended to cause a dedication of any component, step, feature, object, benefit, advantage, or equivalent to the public, regardless of whether it is recited in the claims.

The phrase “means for” when used in a claim embraces the corresponding structure and materials that have been described and their equivalents. Similarly, the phrase “step for” when used in a claim embraces the corresponding acts that have been described and their equivalents. The absence of these phrases means that the claim is not limited to any corresponding structures, materials, or acts.

We claim:

1. A process for modifying a vehicle sound system that includes a radio receiver and/or a media player located in a cavity behind a panel within the vehicle and that is connected to power and audio cables, comprising:
removing the radio receiver and/or media player from the cavity;
disconnecting the power and audio cables from the radio receiver and/or media player;
connecting the power and audio cables to a wireless personal area network receiver; and
positioning the wireless personal area network receiver in the cavity behind the panel.

2. The process of claim 1 further comprising:
inserting the wireless personal area network receiver into a mounting bracket; and
inserting the mounting bracket into a DIN sleeve.

3. The process of claim 2 wherein the inserting the wireless personal area network receiver into the mounting bracket includes inserting the wireless personal area network receiver into a cavity in the mounting bracket that has a shape that is substantially the same as an outer surface of the wireless personal area network.

4. The process of claim 2 wherein the inserting the mounting bracket into the DIN sleeve includes aligning openings in the mounting bracket with corresponding tabs on the interior of the DIN sleeve using a snap action.

5. The process of claim 2 further comprising attaching a semi-transparent cover plate to the mounting bracket.

6. The process of claim 5 wherein the wireless personal area network receiver includes a user-operable control and further comprising removing the semi-transparent cover plate from the mounting bracket and operating the user-operable control through a front-facing opening in the mounting bracket.

7. The process of claim 2 further comprising attaching a back plate to the mounting bracket that is configured to prevent the wireless personal area network receiver from falling out of the bracket, but to allow cables to be attached to the rear of the wireless personal area network receiver.

8. The process of claim 2 further comprising inserting the DIN sleeve into the cavity and locking it into place using a snap action.

9. A kit for modifying a vehicle sound system that includes a radio receiver and/or a media player that is positioned in a cavity behind a panel within the vehicle and that is connected to power and audio cables, comprising:
a wireless personal area network receiver configured to be connected to the power and audio cables in lieu of the power and audio cables being connected to the radio receiver and/or the media player;
a mounting apparatus configured to securely hold the wireless personal area network receiver, to replace the radio receiver and/or the media player with the wireless personal area network receiver, and to securely fit within the cavity behind the panel; and
media containing instructions on how to replace the radio receiver and/or the media player with the wireless personal area network receiver.

10. The kit of claim 9 wherein the mounting apparatus includes:
a DIN sleeve; and
a mounting bracket configured to receive the wireless personal area network receiver and to fit into the DIN sleeve.

11. The kit of claim 10 wherein:
the wireless personal area network receiver has an outer surface; and
the mounting bracket includes a cavity that has a shape that is substantially the same as the outer surface of the wireless personal area network receiver.

12. The kit of claim 10 wherein the DIN sleeve includes inwardly protruding tabs and the mounting bracket includes openings that are configured to snap into the protruding tabs.

13. The kit of claim 10 wherein the mounting bracket has a front-facing portion and wherein the kit further comprises a semi-transparent cover plate configured to attach to the front-facing portion of the mounting bracket.

14. The kit of claim 13 wherein:
the wireless personal area network receiver includes a user-operable control; and
the mounting bracket has a front-facing opening configured to make the user-operable control accessible to a user through the panel when the semi-transparent cover plate is removed from the mounting bracket.

15. The kit of claim 10 wherein:
the mounting bracket has a rear-facing portion; and
the kit further comprises a back plate configured to attach to the rear-facing portion of the mounting bracket and having an opening sized to prevent the wireless personal area network receiver from falling out of the mounting bracket, but to allow power and audio cables to be connected to the wireless personal area network receiver while in front of the back plate.

16. A vehicle sound system, comprising:
a source of power within the vehicle;
one or more audio amplifiers within the vehicle;
power cables connected to the source of power;
audio cables connected to the one or more audio amplifiers; and
a wireless personal area network receiver connected to the power cables and to the audio cables;
wherein the vehicle sound system does not include either a radio receiver or a media player connected by wire to any of the one or more audio amplifiers.

17. The vehicle sound system of claim 16 wherein the vehicle sound system does not include either a radio receiver or a media player connected by wire to the source of power.

18. The vehicle sound system of claim 16 wherein the wireless personal area network receiver is positioned in a cavity behind a panel within the vehicle.

19. The vehicle sound system of claim 18 further comprising a mounting bracket and wherein the wireless personal area network receiver is positioned within the mounting bracket and the mounting bracket is positioned within the cavity behind the panel within the vehicle.

20. The vehicle sound system of claim 19 wherein the mounting bracket has a front portion and wherein the system further comprises a semi-transparent cover plate attached to the front portion of the mounting bracket.

21. The vehicle sound system of claim 20 wherein the semi-transparent cover is flat and does not contain any user-operable controls.

22. The vehicle sound system of claim 21 wherein the semi-transparent cover is configured to be removable from the mounting bracket, wherein the wireless personal area network receiver has a user-operable control, and wherein the mounting bracket includes a front-facing opening through which a user may access the user-operable control after the face plate is removed.

23. The vehicle sound system of claim 19 wherein:
the mounting bracket has a rear portion; and
the system further comprises a back plate attached to the rear portion of the mounting bracket that has an opening sized to prevent the wireless personal area network receiver from falling out of the mounting bracket, but to the allow power and audio cables to be connected to the wireless personal area network receiver while in front of the back plate.
